(19) United States
(12) Patent Application Publication
(10) Pub. No.: US 2009/0283042 A1
(43) Pub. Date: Nov. 19, 2009

(54) SUSCEPTOR POSITIONING AND SUPPORTING DEVICE OF VACUUM APPARATUS

(75) Inventors: Chen-Chung DU, Hsinchu (TW); Muh-Wang Liang, Miaoli (TW); Ching-Huei Wu, Hsinchu (TW); Ming-Tung Chiang, Hsinchu (TW)

Correspondence Address: Muncy, Geissler, Olds & Lowe, PLLC, P.O. BOX 1364, FAIRFAX, VA, 22038-1364, US

(73) Assignee: INDUSTRIAL TECHNOLOGY RESEARCH INSTITUTE

(21) Appl. No.: 12/194,173

(22) Filed: Aug. 19, 2008

(30) Foreign Application Priority Data
May 16, 2008 (TW) 097117969

(51) Int. Cl. C23C 16/00

(52) U.S. Cl. 118/729

(57) ABSTRACT

A susceptor positioning and supporting device of a vacuum apparatus for carrying and elevating a substrate in a vacuum apparatus chamber is provided. The device has a lateral positioning and supporting mechanism to perform clamping and positioning at a side of a susceptor, preventing the susceptor from slanting inside the vacuum apparatus chamber. The lateral positioning and supporting mechanism and the susceptor thereby forms a closed beam support mechanism capable of reducing load suspension deformation at the ends of the large susceptor. The device improves planarity of the large susceptor and the substrate, and in turn improves uniformity of a thin film deposited on the substrate.

### BACKGROUND OF THE INVENTION

1. Field of the Invention

This invention generally relates to a positioning and supporting technique, and more specifically, to a susceptor positioning and supporting device for carrying and elevating a substrate in a vacuum chamber.

2. Description of Related Art

Industries such as semiconductor, Thin-Film Transistor Liquid Crystal Display (TFT LCD), thin-film solar cell, etc. have many common features in techniques, materials, and equipment. As the sizes of electronic products are increasing, the areas of substrates for silicon thin-film solar cell modules, LCD TVs, for example, that are sent into thin-film deposition equipment for process are getting larger. Therefore, in any thin-film deposition equipment, whether for Chemical Vapor Deposition (CVD) or Physical Vapor Deposition (PVD), large-sized susceptor has become an essential element for carrying out large-size thin-film deposition processes.

Particularly, when performing a Plasma Enhanced CVD (PECVD) thin-film deposition process in a vacuum surrounding, a susceptor with heating capability is commonly used as a lower electrode inside the thin-film deposition chamber, and an upper electrode is integrated to the chamber cover of the thin-film deposition chamber, thereby forming a plasma reaction region for ionizing a process gas between the space formed by the upper electrode and the susceptor (lower electrode) in parallel. Then, a thin-film is deposited on the surface of a substrate disposed on the lower electrode. Consequently, in a large-size thin-film deposition process, parallelism between these two electrodes has great influence on the uniformity of the plasma density, and hence is critical to the quality of the thin-film.

Taking a susceptor with heating capability as an example, as shown in FIG. 1A, a robotic arm (not shown) is used for sending a substrate 20 onto a susceptor 401 inside a thin-film deposition chamber 40 of a thin-film deposition apparatus. The susceptor 401 can be a heating device. An elevator mechanism 60 is disposed at the lower surface of the susceptor 40. The elevator mechanism 60 includes an elevator platform 601 penetrating through the thin-film deposition chamber 40, a flexible component 603 connected to the bottom surface of the thin-film deposition chamber 40, a support rack 605 for supporting the susceptor 401, and a sealing element for sealing up the space between the susceptor 401 and the elevator platform 601, thereby maintaining the thin-film deposition chamber 40 in a vacuum state via the sealing element 607. In addition, an elevator actuator 80 for actuating the elevator mechanism 60 is provided. The elevator actuator 80 is connected to the elevator platform 601 via, for example, a lead screw 801, which is used for actuating the susceptor 401 to rise up to a desired height for the deposition process, wherein the susceptor 401 should be kept in parallel with the upper electrode 403. The elevated height S is adjustable as required.

However, there is a sealing gap between the susceptor 401 and the elevator platform 601, and the susceptor 401 having a T-shaped suspension design is supported from the bottom of a center shaft, as shown in FIG. 1B. When the elevator platform 601 is being elevated, the suspension design of the susceptor 401 will make the upper part heavier than the lower part, and the upper part is not restrained. According to the prior art, although the bottom of the center shaft can be fixed in position, swaying and deflection is likely to happen to the susceptor during elevation. In other words, parallelism between the susceptor 401 and the upper electrode 403 is unlikely to be controlled and maintained well.

Moreover, as shown in FIG. 1C, a cantilever beam structure is formed when the susceptor 401 having T-shaped suspension design is supported simply at the center shaft. When performing a large-size thin-film deposition process under high temperature, if no proper support mechanism is provided, then parallelism between the susceptor 401 and the upper electrode 403 is not likely to be maintained due to the weight of the susceptor itself as well as the substrate load on the cantilever beam structure. Similarly, the quality of the thin film is degraded.

According to R.O.C. Patent No. 1228773, positioning pins are disposed on the lower electrode. When the lower electrode is approaching the upper electrode, the positioning pins prop against the surface of the upper electrode and thereby achieving parallelism between the upper and lower electrodes.

However, in practice, the distance between these two electrodes should be adjustable in accordance with the process requirements. However, said patent only provides application for fixed process distance. Furthermore, the susceptor will need a surface area larger than that of the overlaid substrate in order to accommodate the positioning pins. If the susceptor is also a heating device, cost of hardware and power consumption will be unnecessarily increased. Furthermore, this prior art provides no solution for serious deformation at the ends of the cantilever susceptor under high temperature.

According to U.S. Patent Application Publication No. 2006/005409, a plurality of support shafts are disposed underneath the susceptor of the vacuum thin-film deposition apparatus in conjunction with a plurality of small-scaled support boards for supporting the susceptor. However, while supporting the susceptor by said plurality of support boards, this established technique is incapable of knowing whether the susceptor is evenly supported by each of the support boards, in other words, whether the susceptor is slanted. As a result, the quality of thin film is still not assured.

Hence, there is an urgent need in the industry to provide a better technique for positioning and supporting susceptors, which is capable of effectively solve the drawbacks of the prior arts as mentioned above.

### SUMMARY OF THE INVENTION

In view of the disadvantages of the prior art mentioned above, it is a primary objective of the present invention to provide a susceptor positioning and supporting device of a vacuum apparatus, which is capable of assuring of planarity of a susceptor carrying substrate while moving up/down inside a vacuum apparatus chamber.

It is another objective of the present invention to provide a susceptor positioning and supporting device of a vacuum apparatus, which is capable of providing feedback of the position and stance of a susceptor inside a vacuum apparatus chamber from outside the vacuum apparatus chamber.

To achieve the aforementioned and other objectives, a susceptor positioning and supporting device of a vacuum apparatus is provided according to the present invention. The device is used for positioning and supporting a susceptor in a vacuum apparatus. The susceptor is capable of moving up and down inside chamber of the vacuum apparatus, and comprising a substrate carrying part for carrying substrate and a susceptor center shaft part connected to the susceptor carrying part. The susceptor positioning and supporting device of vacuum apparatus comprises: a slide mechanism, which is in parallel with a thin-film deposition chamber for sustaining the susceptor center shaft part; and a lateral positioning and supporting mechanism, which further comprises a plurality of clamp sets fixed to the slide mechanism for clamping at the side of susceptor, a plurality of clamp set drivers separately connected to each of the clamp sets for enabling each of the clamp sets to move simultaneously, a plurality of limiters connected to the slide mechanism for restricting the location of each clamp set and preventing the susceptor from slant, and a clamp set motion module for guiding each clamp set to move.

In said susceptor positioning and supporting device of the vacuum apparatus, the slide mechanism may comprise: an elevator platform, which is horizontally disposed in parallel with the thin-film deposition chamber, comprising a plurality of first perforations and a second perforation, and the second perforation allows the susceptor center shaft part to penetrate; linear bearings penetrating each of the first perforations; guide posts integrated with the linear bearings and fixed to the bottom of the thin-film deposition chamber, thereby capable of guiding the elevator platform to move up and down against the thin-film deposition chamber; and an elevator actuator for actuating the elevator platform; wherein the elevator actuator may comprise a leadscrew connected to the elevator platform.

In said lateral positioning and supporting mechanism, the plurality of clamp sets are disposed symmetrically around the center axis of the second perforation of the elevator platform, each clamp set comprises a clamp claw part for contacting with the side of the substrate carrying part, a clamp main part, wherein one end of the clamp main part is connected to the clamp claw part, and a connection component disposed on the clamp main part. In one embodiment, the clamp set motion module comprises a slide block and a slide track on the elevator platform, the slide track is fixed to the elevator platform, and the clamp main part is integrated and fixed to the slide block thereby capable of sliding on the slide track freely, accordingly allowing parallel motion of the plurality of clamp sets. In another embodiment, the clamp set motion module comprises a rotating shaft allocated to the elevator platform, and the clamp main part is integrated to the elevator platform via the rotating shaft, accordingly allowing swaying motion of the plurality of clamp sets. Also, the connection component can be integrated to the clamp main part or an additional structure connected to the clamp main part. In other words, those skilled in the art can readily modify the structure and position related to the clamp sets and motion of the clamp set motion module without departing from the spirit of the present invention.

It should be noted herein that the clamp claw part and susceptor side may comprise corresponding protruding part and sunken part, for instance, the substrate carrying part may have a protruding part or sunken part, or the susceptor may not have a protruding part or sunken part feature. If a susceptor has no protruding part nor sunken part, then for example a positioner can be provided at the side of the substrate carrying part, thereby enabling the positioner and the clamp claw part to have corresponding protruding part and sunken part, thereby achieving the same objective of lateral positioning and support. Certainly, said corresponding protruding part and sunken part may be rectangle, cylinder, arc, or with any other equivalent shape capable of achieving purpose of lateral positioning and support. In addition, the clamp set drivers are for providing the opposite clamp sets with driving power to perform open/close motion, the clamp set driver may comprise, for example, a pneumatic cylinder or motor. In one embodiment, the clamp set driver comprises a pneumatic cylinder and a sliding adapter connected to the pneumatic cylinder. The cylinder further comprises a cylinder block fixed to the elevator platform and a cylinder shaft, one end of said cylinder shaft is connected with the sliding adapter. Also, the pneumatic cylinder may be, for example, a bi-headed pneumatic cylinder. The sliding adapter is for connecting the cylinder shaft to the clamp main part of the clamp set, but not restricted thereto.

In addition, the limiter can be a stopper perpendicular to the slide mechanism, and each of the limiters is disposed symmetrically around axis of the second perforation of the elevator platform, and being allocated at the other side of the clamp set driver. In one embodiment, the limiter is perpendicularly fixed to the elevator platform and is located at the other end of the cylinder shaft.

In an implementation that requires vacuum surrounding, the susceptor center shaft part penetrates through the second perforation, and a sealing element can be disposed in the second perforation to maintain the thin-film deposition chamber in a vacuum state. Between each connection component of the clamp set and lower surface of the thin-film deposition chamber is disposed a second flexible sealing element, and between upper surface of the elevator platform and the lower surface of the thin-film deposition chamber is disposed with a first flexible sealing element. For instance, wherein the second flexible sealing element is fixed to each of the connection components for maintaining the thin-film deposition chamber in a vacuum state, and preferably, being capable of moving correspondingly with the clamp claw part. The first flexible sealing element can be fixed, for example, between the upper surface of the elevator platform and the lower surface of the thin-film deposition chamber to maintain the thin-film deposition chamber in a vacuum state, and is an integrated structure for allowing only vertical relative movement.

In addition, the susceptor positioning and supporting device of the vacuum apparatus of the preset invention can further comprises a susceptor position indicator for indicating the position of the susceptor. The susceptor position indicator may be a pointer connected to the clamp set driver, for example, connected to one end of the cylinder shaft away from the sliding adapter. Also, the slide mechanism is provided with a graduated scale corresponding to the pointer, which can be a linear or curve-shaped graduated scale.

In summary, the susceptor positioning and supporting device of the vacuum apparatus according to the present invention employs a lateral positioning and supporting mechanism that is disposed symmetrically around the center axis of the second perforation of the elevator platform. With the susceptor penetrating the second perforation and the sides of the susceptor being clamped by the lateral positioning and supporting mechanism, the susceptor can thus be prevented from slanting inside the chamber. The mechanism and the susceptor also form a closed beam support structure that reduces edge drooping of large-sized susceptor, thereby achieving planarity for large-sized susceptors and uniformity for thin-film deposition. In addition, the actual position and stance of the susceptor can be monitored from outside of the chamber, in particular, in Capacitive Coupling Plasma (CCP) system application, the parallelism between two electrodes can be improved to obtain uniform plasma density. Therefore, the present invention enhances uniformity of large thin-film deposition processes for fabricating of TFT LCD and thin-film solar cell etc., thereby obtaining thin films with excellent quality.

### BRIEF DESCRIPTION OF DRAWINGS

The present invention can be more fully understood by reading the following detailed description of the preferred embodiments, with reference made to the accompanying drawings, wherein:

FIGS. 1A through 1C are diagrams illustrating a prior susceptor;

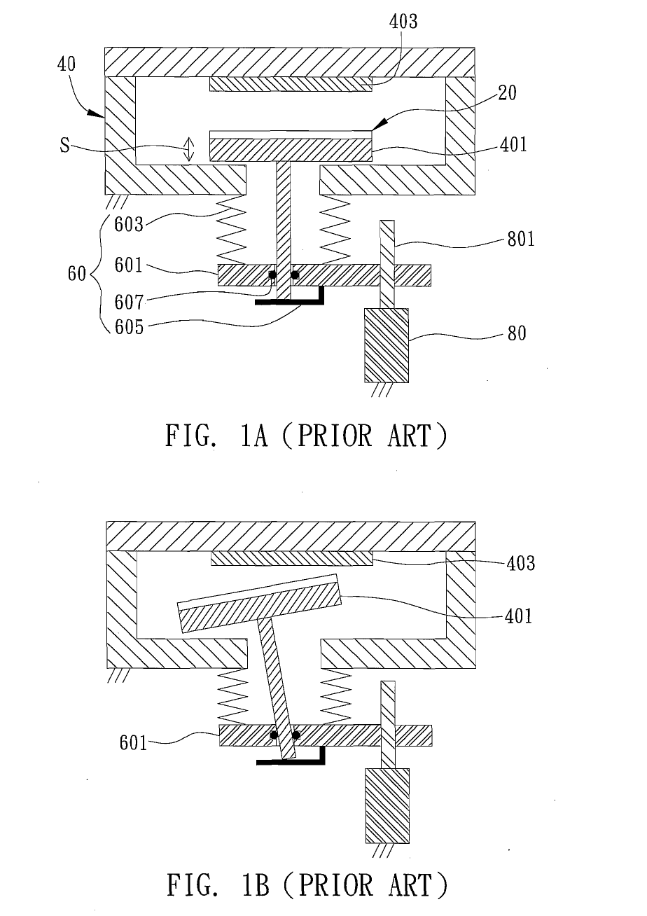

FIG. 2 is a diagram illustrating a first embodiment of the susceptor positioning and supporting device of a vacuum apparatus of the present invention;

FIG. 3 is a diagram illustrating a modified embodiment of the susceptor used in FIG. 2;

FIG. 4A is a diagram illustrating a second embodiment of the susceptor positioning and supporting device of a vacuum apparatus of the present invention, wherein corresponding structures of clamp claw part and substrate carrying part are modified; and

FIG. 4B is a diagram illustrating a third embodiment of the susceptor positioning and supporting device of a vacuum apparatus of the present invention, wherein the mechanism for clamp set motion and corresponding structures of clamp claw part and substrate carrying part are modified.

### DETAILED DESCRIPTION OF PREFERRED EMBODIMENTS

The following illustrative embodiments are provided to illustrate the embodiments of the present invention. Those skilled in the art can readily understand these and other advantages and effects upon reviewing the disclosure of this specification.

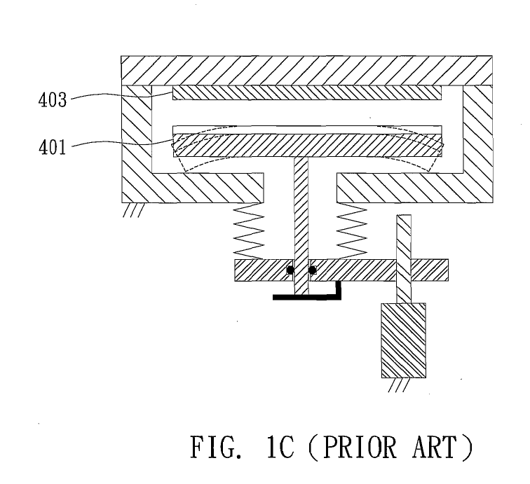

FIG. 2 is a diagram illustrating a first embodiment of the susceptor positioning and supporting device for a vacuum apparatus of the present invention. As shown in the FIG. 2, the susceptor positioning and supporting device of the vacuum apparatus of the present embodiment is used for positioning and supporting a susceptor 10 in a thin-film deposition chamber 40 of the vacuum apparatus. The susceptor 10 is capable of moving up and down inside the thin-film deposition chamber 40, and it includes a substrate carrying part 101 for carrying a substrate (not shown), and a susceptor center shaft part 103 connected to the substrate carrying part 101. The center axis of the susceptor 10 is also the center axis of both the susceptor center shaft part 103 and the substrate carrying part 101. The thin-film deposition chamber 40 can be a vacuum thin-film deposition chamber with an upper electrode 403 disposed on the chamber cover thereof, but not limited thereto. The present invention is also applicable to other types of chamber, for instance, a chamber without the upper electrode 403.

It should be noted that, the susceptor 10 itself can be a heating component while carrying the substrate. Therefore, the substrate carrying part 101 can be a heating plate. However, the susceptor 10 can also be a simple carrier for carrying the substrate without the heating capability; or the susceptor 10 itself can be an electrode, e.g. a lower electrode in parallel with the upper electrode 403. In other words, the present embodiment simply provides an illustration of one of applicable modes, and the present invention is not limited thereto. Furthermore, the present embodiment is applicable to Capacitive Coupling Plasma (CCP) system, but application of the present invention is not limited thereto.

The susceptor positioning and supporting device of the vacuum apparatus includes a slide mechanism 1 disposed in parallel with and under the thin-film deposition chamber 40, and a lateral positioning and supporting mechanism 3 disposed at the slide mechanism 1 for performing positioning/supporting by clamping from the sides of the susceptor 10.

The slide mechanism 1 is for maintaining the bottom of the susceptor center shaft part 103. In the present embodiment, the slide mechanism 1 includes an elevator platform 11, linear bearings 13 disposed at the elevator platform 11, guide posts 15 connecting the thin-film deposition chamber 40 and the elevator platform 11, and an elevator actuator 17 for actuating the elevator platform 11 to move up and down.

The elevator platform 11 is in parallel with the thin-film deposition chamber 40, and it includes a plurality of first perforations 111 and a second peroration 112. The second perforation 112 is disposed in the elevator platform 11 for allowing the susceptor center shaft part 103 to penetrate. The plurality of first perforation 111 is disposed in the upper and lower portions of the elevator platform 11 correspondingly to the guide posts 15. Each of the linear bearings is disposed to penetrate one of the first perforations 111. In the present embodiment, the second perforation 112 is disposed in the center or near the center of the elevator platform 11. A sealing element 6 is provided in the second perforation 112 capable of maintaining the thin-film deposition chamber 40 in a vacuum state. For instance, the sealing element 6 can be a seal ring, an O-ring, or any other equivalent component capable of sealing the second perforation 112 for maintaining the thin-film deposition chamber 40 in a vacuum state.

The guide posts 15 penetrating the elevator platform 11 and in corporation with the linear bearings 13 are fixed to the thin-film deposition chamber 40. In the present embodiment, two or more guide posts 15 are vertically connected underneath the external bottom of the chamber 40, the guide posts working in corporation with the linear bearings 13 and fixed to the chamber 40, thereby guiding the elevator platform 11 move up and down in parallel against the thin-film deposition chamber 40. However, the location and number of guide posts not restricted to those stated herein. Since the elevator platform 11 can be guided by the guide posts 15 to move up and down relative to the thin-film deposition chamber 40, the slide mechanism 1 provides low manufacturing cost and easy fabrication.

In the present embodiment, a first flexible sealing element 7 is fixed between the upper surface of the elevator platform 11 and the lower surface of the thin-film deposition chamber 40. More specifically, two ends of the first flexible sealing element 7 is separately fixed to the upper surface of the elevator platform 11 and the lower surface of the thin-film deposition chamber 40, allowing only vertical movement. Also, the thin-film deposition chamber 40 is maintained in a vacuum state.

The elevator actuator 17 includes a lead screw 171 connected to the elevator platform 11 for actuating the elevator platform 11 to move up and down against the thin-film deposition chamber 40, thereby forming a single-axis elevator platform, as indicated by arrows A in FIG. 2. In the present embodiment, the lead screw 171 is penetrated through the lower portion of the elevator platform 11 and located near the center of the elevator platform 11.

The lateral positioning and supporting mechanism 3 is disposed at the elevator platform 11 of the slide mechanism 1, including: a plurality of clamp sets 31 fixed to the elevator platform 11 of the slide mechanism 1 for clamping at sides of the susceptor 10, a plurality of clamp set drivers 33 individually connected to each of the clamp sets for enabling each of the clamp sets 31 to move simultaneously, a plurality of limiters 35 connected to the slide mechanism 1 for restricting the position of each of the clamp sets and thus preventing the susceptor deviating from the center axis, a plurality of clamp set motion modules 37 for limiting the kind of motion for each of the clamp sets 31, and a plurality of susceptor position indicator 39 for indicating the position of the susceptor 10 inside the vacuum chamber 40.

The plurality of clamp sets 31 are fixed to the slide mechanism 1 and disposed symmetrically around the center axis of the second perforation 112 of the elevator platform 11. Each of the clamp sets 31 includes a clamp claw part 311, a clamp main part 313, wherein an end of the clamp main part 313 is connected to the clamp claw part 311, and a connection component 315 connected with the clamp main part 313. In the present embodiment, the plurality of clamp sets 31 is fixed to the elevator platform 11. In one example, four clamp sets 31 can be provided, each pair of clamp sets 31 are disposed symmetrically around the center axis of the second perforation 112 of the elevator platform 11. Since the susceptor 10 is penetrated through the second perforation 112, the plurality of clamp sets 31 performs lateral positioning movement, thus allowing the center of the susceptor 10 to spontaneously align with the center of the second perforation 112. However, in another embodiments, the number of clamp sets can be adjusted while the susceptor 10 still maintaining spontaneously alignment with the center of the second perforation 112, as long as the adjustment is based on the shape of the substrate carrying part 101 of the susceptor 10.

The clamp claw part 311 and the substrate carrying part 101 include a corresponding protruding part and a sunken part, respectively, thereby enabling the protruding part of the clamp claw part 311 to engage in the corresponding sunken part at each side of the substrate carrying part 101 for positioning purpose, consequently keeping the susceptor 10 from deflection and enabling the clamp claw parts 311 to provide support at the sides of the substrate carrying part 101, and further preventing ends of the substrate carrying part 101 from drooping due to substrate load and the weight of substrate carrying part 101. In the present embodiment, the clamp claw part 311 is provided with a roughly rectangular protruding part, and the substrate carrying part 101 has a corresponding rectangular sunken part. Also, the length of the protruding part is longer than the depth of the sunken part for enabling the clamp claw parts 311 to position and keep contacting at the sides of the substrate carrying part 101. Certainly, in other embodiments, those skilled in the art can choose the length of the protruding part to be equal to or shorter than the depth of the sunken part, or, for instance, the clamp claw part 311 is provided with a roughly pillar-shaped protruding part, and then the substrate carrying part 101 has a corresponding pillar-shaped sunken part, but they are not restricted to those stated in the present embodiment. In other words, any equivalent structure that is capable of enabling the clamp claw parts 311 to position and support at the sides of the susceptor 10 falls in the scope of the present invention.

In addition, in the present embodiment, since each clamp set 31 penetrates through the elevator platform 11 and enters the thin-film deposition chamber 40. In order to maintain the thin-film deposition chamber 40 in a vacuum state, a second flexible sealing element 9 capable of simultaneously moving along with a clamp set 31 can be provided. One end of the second flexible sealing element 9 is fixed and integrated to the bottom surface of the thin-film deposition chamber 40, and the other end is fixed to the connection component 315 instead of the upper surface of the elevator platform 11. The second flexible sealing 9 is sealed to the connection component 315, and can be made of metal, leather, rubber or other flexible vacuum sealing element.

Each of the clamp sets 31 is driven by one clamp set driver 33, allowing each of the clamp sets 31 to move simultaneously and symmetrically around the center axis of the susceptor 10 penetrating the second perforation 112. The limiters 35 also allows the clamp claw parts 311 to directly contact the sides of the substrate carrying part 101, positioning and supporting the susceptor 10 to maintain planarity of the substrate carrying part 101.

In the present embodiment, each of the clamp set drivers 33 is respectively connected to a clamp main part 313. The clamp set drivers 33 provides the clamp set 31 with driving power. The clamp set driver 33 can include a pneumatic cylinder and a sliding adapter 330 integrated to the pneumatic cylinder. The pneumatic cylinder further comprises a cylinder block 331 that is fixed to the elevator platform 11 and a pneumatic cylinder shaft 333, wherein one end of the cylinder shaft 333 is integrated to approximately the middle of the clamp main part 313 via the sliding adapter 330. Accordingly, the clamp set drivers 33 are, for example, bi-headed pneumatic cylinders, and the cylinder shaft 333 is coupled to the corresponding clamp main part 313 via, for example, the sliding adapter 330, in order to drive the clamp sets 31.

It should be understood that, although a plurality of clamp set drivers 33 are used to respectively connect with a plurality of clamp sets 31 in this embodiment, however, those skilled in the art can also use a single clamp set driver 33 to control all clamp sets 33 to move simultaneously. Other approaches can be adopted to respectively control simultaneous movement of each of the clamp sets 33. In addition, in other embodiments, those skilled in the art can alternatively use other equivalent clamp set driver capable of driving the clamp set 31, as long as the equivalent clamp set driver is capable of controlling the lateral movement of each of the clamp sets 33, for instance, other types of pneumatic cylinder, motor, or other clamp set driver having lateral driving capability. Moreover, the sliding adapter 330 can be omitted and that the clamp set driver 33 is directly coupled to the clamp claw part 311.

The limiter 35 can be a stopper disposed perpendicularly to the slide mechanism 1, for example, perpendicularly fixed to the elevator platform 11 and located at the other end of the clamp set driver 33. In the present embodiment, one limiter 35 is disposed on the elevator platform 11 corresponding to one of the clamp sets 31 and is located at the other end of the cylinder shaft 333.

Furthermore, the limiters 35 allow all of the clamp sets 31 to have a symmetrical axis around the center of the second perforation 112, namely, one end of the clamp set driver 33 is stopped by the limiter 35, thereby limiting the clamp claw part 311 of each clamp set 31, so that the center axis of the susceptor 10 overlaps with the center axis of the second perforation 112. Also, the susceptor 10 is kept horizontal without slant.

The clamp set motion modules 37 can be disposed on the elevator platform 11 of the slide mechanism 1. In the present embodiment, the clamp set motion module 37 can be a slide module corresponding to each of the clamp sets 31. It includes a slide block 371 connected to the clamp set 31 and a slide track 373 for the slide block 371 to slide freely thereon. By integrating the clamp main part 313 of the clamp set 31 with the slide block 371, each of the clamp sets 31 is capable of sliding freely on the slide track 373 and maintaining a parallel movement, thus allowing the clamp claws to move in parallel. One purpose of which is to enable the claws of the clamp set 37 to move horizontally for accommodating heat expansion of the susceptor 10.

Accordingly, the sliding adapter 330 can be replaced by the slide block 371, such that the slide block 371 of the clamp set motion module 37 is directly coupled with the clamp main part 313 and the cylinder shaft 333. Since the technique of directly coupling the clamp main part 313 and the cylinder shaft 333 with the sliding block 371 is well known in the art, thus no further description will be provided.

The susceptor position indicator 39 can be disposed at one side of each of the clamp set drivers 33. In the present embodiment, the susceptor position indicator 39 is connected to one end of the cylinder shaft 333 of the clamp set driver 33, for instance, connected to one end of the cylinder shaft 333 away from the sliding adapter 330. It can be a pointing device having a sharp pointer. The slide mechanism 1 can be provided with a graduated scale 113 at a place corresponding to the pointer, for example, at the lower surface of the elevator platform 11, wherein the graduated scale 113 can, for example, be a linear or curved graduated scale.

In the present embodiment, the clamp claw parts 311 maintains contact with the sides of the substrate carrying part 101 inside the vacuum thin-film deposition chamber 40, therefore, by using such clamp structure, along with the susceptor position indicator 39 and the graduated scale 113 fixed to the elevator platform 11, position of the susceptor 10 inside the thin-film deposition chamber 40 can be perceived accurately from outside the thin-film deposition chamber 40. The clamp set drivers 33 are also capable of performing individual precision adjustment over clamping force of the clamp sets for positioning susceptor and controlling position and motion thereof. Certainly, location of the susceptor position indicator 39 is not restricted to that stated herein. Rather, it can also be disposed inside the elevator platform 11 or other location. Therefore, any susceptor position indicator 39, as long as being capable of indicating the position and motion of the susceptor 40 inside the thin-film deposition chamber 40 is applicable to the present invention. In other words, any external device of the vacuum thin-film deposition chamber 40, which is capable of accurately indicating the position or motion of susceptor inside the vacuum thin-film deposition chamber 40, for example, the substrate carrying part 101 of the susceptor 10, is applicable to the present invention. In addition, the ability to individually and precisely adjust the clamping force in order to control the susceptor position and motion is applicable to any stage of the process, i.e. before process, during the process, and after process.

Therefore, with foresaid supporting and positioning mechanism disclosed by the present invention, a closed beam supporting and positioning structure of high rigidity can be formed with the susceptor 10, increasing planarity of a large-sized susceptor and enhancing uniformity of thin-film thickness in large-size thin-film deposition application.

It should be noted that, since a clamp set driver 33 such as a pneumatic cylinder for adjusting pressure and an in house mechanical structure for measuring distance are well-known techniques, no detailed description is given hereafter.

There are certainly other modifications to the present invention. For instance, a susceptor without heating capability can be used, or a traditional normal susceptor such as one without lateral sunken feature can also be used.

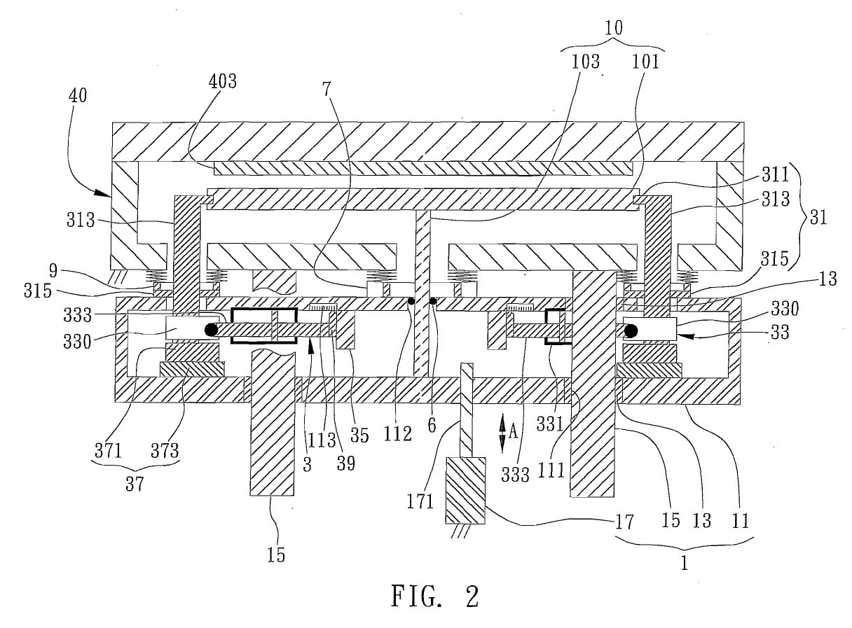

As shown in FIG. 3, many modifications can be derived from the first embodiment. For instance, a lateral positioner 5 at the side of the susceptor 10 can be used instead of the aforementioned lateral sunken feature. This positioner 5 can be connected to the side of substrate carrying part 101 of the susceptor 10 by means of soldering, riveting, or other equivalent technique. A sunken part can be provided in the positioner 5 corresponding to the clamp claw part 311, thereby enabling the clamp claw part 311 and the positioner 5 to engage at the side of the susceptor 10 for positioning and support, without the need to changing the side structure of the susceptor 10. The corresponding protruding and sunken parts can certainly be arc-shaped or other equivalent shape capable of achieving the objective of lateral positioning and support, and are not restricted to only the shapes illustrated in FIGS. 2 and 3.

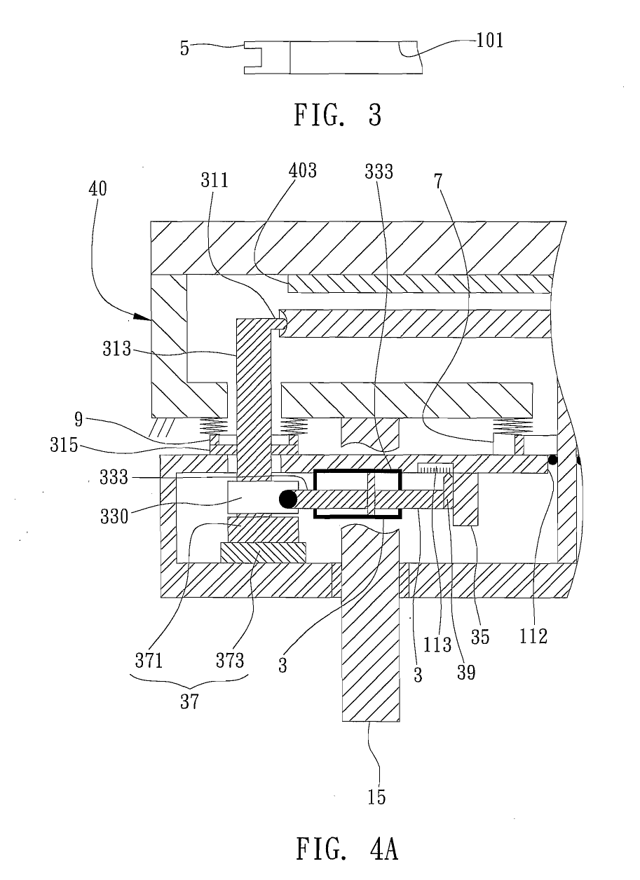

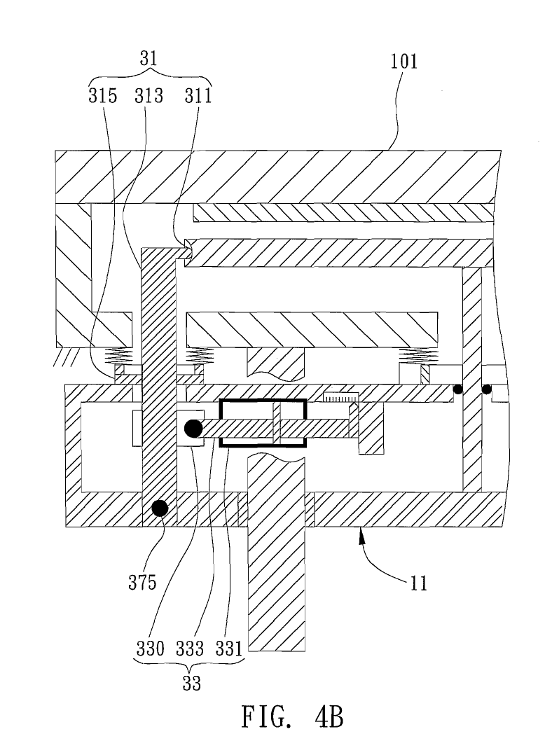

Referring to FIG. 4A, which is a diagram illustrating a second embodiment of the susceptor positioning and supporting device of the vacuum apparatus of the present invention, components that are the same as or similar to those in the first embodiment are designated by the same symbols and no detailed description will be given hereafter.

The difference between the first and second embodiments is in that the clamp claw part 311 includes an arc-shaped protruding part, and the side of the susceptor 10 has a corresponding arc-shaped sunken part. Accordingly, the arc-shaped protruding part of the clamp claw part 311 has a larger diameter, while the corresponding arc-shaped sunken part at clamped side of the substrate carrying part 101 has a smaller diameter, not necessarily forming a tightly clamp relationship at the substrate carrying part 101. Therefore, by providing lateral clamp force to maintain contact with the side of the substrate carrying part 101, the clamp claw part 311 is capable of supporting the periphery of the substrate carrying part 101, and forming a closed beam support structure of high rigidity with the susceptor 10. In addition, by using the susceptor position indicator 39 for controlling feedback of the susceptor position and clamping force for adjusting the clamp set driver 33, susceptor can be maintained in a horizontal position while forming a closed beam structure for supporting the ends of the substrate carrying part 101.

In other embodiments, a positioning frame (not shown) can further be provided (e.g. an arc-shaped sunken part) that corresponds to the shape of protruding part of the clamp claw part 311 to fix and encase the side of the substrate carrying part 101, replacing the substrate carrying part 101 having an arc-shaped sunken part as shown in FIG. 2, or replacing the positioner 5 provided at the side of the susceptor 10 as shown in FIG. 3. Certainly, the corresponding protruding part and sunken part disposed at the clamp claw part 311 and the substrate carrying part 101 are not restricted to said rectangular, pillar-shaped, or arc-shaped, other protruding part and sunken part of equivalent shapes for performing support/clamping at the side of the susceptor 10 are also applicable.

In addition, although in foresaid embodiments, the substrate carrying part 101, the positioner 5, or the positioning frame having sunken part are used, in other embodiments, the structures of the substrate carrying part 101, the positioner 5, or the positioning frame can be modified. For instance, the substrate carrying part 101, the positioner 5, or the positioning frame can be designed to have a protruding part, whereas the clamp claw part 311 has a corresponding sunken part. In other words, any equivalent structure as long as being capable of supporting/clamping at peripheral side of the susceptor 10 is applicable to the present invention.

Referring to FIG. 4B, which illustrates a third embodiment of the susceptor positioning and supporting device of the vacuum apparatus of the present invention, components that are the same as or similar to those in the previous embodiments are designated with same symbols and no detailed description will be given hereafter.

The present embodiment is different from the previous embodiments in that the clamp set motion is modified. For instance, the clamp set motion module is modified by providing a clamp set motion module that comprises a rotating shaft to replace said slide block and said slide track.

As shown in FIG. 4B, a clamp swaying structure is formed by using a rotating shaft 375 that couples the clamp main part 313 of the clamp set 31 to the elevator platform 11. In this embodiment, the clamp claw part 311 and substrate carrying part 101 can include corresponding arc-shaped protruding and sunken parts. Since the clamp set 31 and the susceptor 10 contact to form a closed beam structure, and also the clamp set driver 33 is capable of sustaining the structure from deformation, the clamp main part 313 is axially connected to one end of the rotating shaft 375. In other words, the rotating shaft 375 provides support for the claws and in turn the end of the susceptor 10 experiencing a downward force as a result of its own weight and the load. Meanwhile, the arc-shaped protruding part of the clamp claw part 311 forms a contact point with the corresponding smaller diameter arc-shaped sunken part of clamped side of substrate carrying part 101, thus providing another embodiment of the present invention capable of accommodating heat expansion. Therefore, when the susceptor is heated, although heat deformation is likely to happen to the substrate carrying part 101, support capability of the closed beam structure is maintained unchanged. Also with benefit of the susceptor position indicator 39 for monitoring and providing feedback of susceptor position, as well as ability to adjust the clamping force by adjusting the clamp set driver 33, the susceptor can be maintained in a horizontal position while forming a closed beam structure for supporting the ends of the substrate carrying part 101.

The present invention is capable of maintaining planarity of large substrates while avoiding susceptor deflection or edge drooping occurred in the prior art. When applied to the capacitive coupling plasma application, parallelism between two electrodes can be improved, enhancing uniformity of large thin-film deposition processes for fabricating of TFT LCD and thin-film solar cell etc., thereby obtaining thin films with excellent quality.

In summary, the susceptor positioning and supporting device of the vacuum apparatus according to the present invention prevents the susceptor to deviate from the center while providing support at the sides of the susceptor by employing the clamp sets and forming a closed beam support structure of high rigidness, thereby achieving planarity for large-size susceptors. Furthermore, in particular, in Capacitive Coupling Plasma (CCP) system applications, the parallelism between two electrodes can be maintained to increase uniformity of the thin film. In addition, the actual position and stance of the susceptor inside vacuum apparatus chamber can be monitored from outside the vacuum apparatus chamber. Therefore, the present invention is capable of solving many drawbacks of the prior art and provides high industrial value.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A susceptor positioning and supporting device of a vacuum apparatus for positioning and supporting a susceptor in the vacuum apparatus, the susceptor capable of moving up and down inside a thin-film deposition chamber of the vacuum apparatus comprising a substrate carrying part for carrying a substrate and a susceptor center shaft part connected to the substrate carrying part, the susceptor positioning and supporting device comprising:
a slide mechanism in parallel with the thin-film deposition chamber for maintaining the susceptor center shaft part; and
a lateral positioning and supporting mechanism comprising a plurality of clamp sets fixed to the slide mechanism for clamping at sides of the susceptor, a plurality of clamp set drivers separately connecting with one of the clamp sets for enabling each of the clamp sets to move simultaneously, a plurality of limiters connected to the slide mechanism for restricting position of each clamp set and preventing slant of the susceptor, and a clamp set motion module for guiding each of the clamp sets to move.

2. The susceptor positioning and supporting device of the vacuum apparatus of claim 1, wherein the slide mechanism comprises:
an elevator platform in parallel with the thin-film deposition chamber and comprising a plurality of first perforations and a second perforation, the susceptor center shaft part penetrating through the second perforation;
linear bearings, each penetrating one of the first perforations;
guide posts in corporation with the linear bearings and fixed to the thin-film deposition chamber for guiding the elevator platform to move up and down in parallel against the thin-film deposition chamber; and
an elevator actuator for actuating the elevator platform.

3. The susceptor positioning and supporting device of the vacuum apparatus of claim 2, wherein a first flexible sealing element is fixed between the upper surface of the elevator platform and a lower surface of the thin-film deposition chamber.

4. The susceptor positioning and supporting device of the vacuum apparatus of claim 2, wherein a sealing element is disposed inside the second perforation.

5. The susceptor positioning and supporting device of the vacuum apparatus of claim 2, wherein the elevator actuator comprises a lead screw connected to the elevator platform.

6. The susceptor positioning and supporting device of the vacuum apparatus of claim 1, wherein a second flexible sealing element is disposed between each of the clamp sets and the lower surface of the thin-film deposition chamber.

7. The susceptor positioning and supporting device of the vacuum apparatus of claim 6, wherein each of the clamp sets comprises a clamp claw part for contacting side of the substrate carrying part, a clamp main part, wherein one end of the clamp main part is connected to the clamp claw part, and a connection component that is disposed on the clamp main part for connecting with the second flexible sealing element.

8. The susceptor positioning and supporting device of the vacuum apparatus of claim 7, wherein the clamp claw part and the substrate carrying part comprise corresponding protruding and sunken parts.

9. The susceptor positioning and supporting device of the vacuum apparatus of claim 8, wherein the length of the protruding part is longer than the depth of the sunken part.

10. The susceptor positioning and supporting device of the vacuum apparatus of claim 8, wherein a positioner is disposed at a side of the substrate carrying part, the positioner and the clamp claw part having corresponding protruding and sunken parts.

11. The susceptor positioning and supporting device of the vacuum apparatus of claim 1, wherein each of the clamp set comprises a clamp claw part for contacting a side of the substrate carrying part, a clamp main part, wherein an end of the clamp main part is connected to the clamp claw part, and a connection component that is disposed on the clamp main part.

12. The susceptor positioning and supporting device of the vacuum apparatus of claim 11, wherein the clamp claw part and the substrate carrying part comprise corresponding protruding and sunken parts.

13. The susceptor positioning and supporting device of the vacuum apparatus of claim 12, wherein the length of the protruding part is longer than the depth of the sunken part.

14. The susceptor positioning and supporting device of the vacuum apparatus of claim 12, wherein a positioner is disposed at a side of the substrate carrying part, the positioner and the clamp claw part having corresponding protruding and sunken parts.

15. The susceptor positioning and supporting device of the vacuum apparatus of claim 1, wherein each of the clamp set drivers comprises a pneumatic cylinder and a sliding adapter connected to the pneumatic cylinder.

16. The susceptor positioning and supporting device of the vacuum apparatus of claim 15, wherein the pneumatic cylinder comprises a cylinder block and a cylinder shaft.

17. The susceptor positioning and supporting device of the vacuum apparatus of claim 15, wherein the pneumatic cylinder is a bi-headed pneumatic cylinder.

18. The susceptor positioning and supporting device of the vacuum apparatus of claim 1, wherein the clamp set driver comprises a motor.

19. The susceptor positioning and supporting device of the vacuum apparatus of claim 1, wherein each of the clamp set motion module comprises a slide block connected to one of the clamp sets and a slide track allocated to the slide mechanism for allowing the slide block to slide freely.

20. The susceptor positioning and supporting device of the vacuum apparatus of claim 1, wherein the clamp set motion module comprises a rotating shaft for positioning the clamp set to the slide mechanism.

21. The susceptor positioning and supporting device of the vacuum apparatus of claim 1, wherein the limiter is a stopper disposed perpendicular to the slide mechanism, and located at the other end of the clamp set driver.

22. The susceptor positioning and supporting device of the vacuum apparatus of claim 1, further comprising a susceptor position indicator connected to the clamp set driver for indicating position of the susceptor.

23. The susceptor positioning and supporting device of the vacuum apparatus of claim 22, wherein the susceptor position indicator is a pointer that is connected to the clamp set driver, and the slide mechanism is provided with a graduated scale corresponding to the pointer.
